(19) United States
(12) Patent Application Publication
(10) Pub. No.: US 2007/0077755 A1
(43) Pub. Date: Apr. 5, 2007

(54) Method of forming metal wiring in a semiconductor device

(76) Inventor: Ji Ho Hong, Suwon-city (KR)

Correspondence Address: MCKENNA LONG & ALDRIDGE LLP;Song K. Jung, 1900 K Street, N.W., Washington, DC, 20006, US

(21) Appl. No.: 11/320,705

(22) Filed: Dec. 30, 2005

(30) Foreign Application Priority Data
Oct. 4, 2005 (KR) 10 2005-0093003

(51) Int. Cl. H01L 21/44

(52) U.S. Cl. 438/627; 438/652; 438/653; 438/674

(57) ABSTRACT

A method for forming metal wiring in a semiconductor device includes forming a first metal wiring, an etch stopping layer, and an interlayer insulation film on a semiconductor substrate. A via-hole and a trench are respectively formed by selectively removing a portion of the interlayer insulation film. The etch stopping layer is selectively removed to expose a surface of the first metal wiring. An oxidation film is formed on an entire surface of the semiconductor substrate. A de-gas process is performed on the semiconductor substrate and the oxidation film is removed. A metal diffusion barrier film is provided on an entire surface of the semiconductor substrate. A second metal wiring is formed on a metal seed layer, which has a thickness in a range of 750 to 850 Å on the metal diffusion barrier film.

This application claims the benefit of Korean Patent Application No. P2005-93003, filed on Oct. 4, 2005, which is hereby incorporated by reference as if fully set forth herein.

### BACKGROUND OF THE INVENTION

1.Field of the Invention

The present invention relates to a method of fabricating a semiconductor device, and more particularly, to a method of forming metal wiring in a semiconductor device.

2. Discussion of the Related Art

With the advent of the ultra-large scale integration (ULSI) semiconductor era, the size of a chip is reducing to sub-half micron geometry, while circuit density is increasing to improve performance and reliability. For this purpose, a copper film is widely used in a process of forming metal wiring in a semiconductor device because copper has a relatively high melting point in comparison with aluminum and high electro migration (EM) resistance, so that reliability of a semiconductor product can be improved and a signal transmission speed can increase due its low resistivity. Therefore, the copper film is a useful interconnection material for an integration circuit.

Recently, available methods for burying copper in a semiconductor device requires a physical vapor deposition (PVD)/reflow process, a chemical vapor deposition (CVD) process, an electro-plating process, an electroless-plating process, and the like. The electroless-plating technique results in superior gap-filling capability and fast growth even in a high aspect ratio, but it has a small grain size. Therefore, the electroless-plating process has low electro migration resistance and requires some complicated chemical reactions, rendering it difficult to control. On the contrary, the electro-plating process has numerous advantages such as fast growth speed, a relatively simple chemical reaction, a large grain size, and high electro migration resistance. Also, an excellent quality of film can be obtained. Therefore, the electro-plating process is widely used for forming a copper layer.

Unfortunately, the process of burying copper wiring for the electro-plating process has various defects 10 that can affect properties of a semiconductor device. For example, voids 10 and/or seams 10, generated in a trench or a via-hole in which copper is buried as shown in FIG. 1, are considered defects. Therefore, many efforts are being made to reduce such defects in the art. In FIG. 1, reference numeral 11 denotes a semiconductor substrate, 12 denotes a first copper wiring, 13 denotes a nitride film, 14 denotes an interlayer insulation film, 19 denotes a metal diffusion barrier, and 20 denotes a second copper wiring.

### SUMMARY OF THE INVENTION

The present invention has been made to overcome the aforementioned problems. An object of the present invention is to provide a method of forming metal wiring in a semiconductor device, which is configured to prevent voids and/or seams in a metal layer from being buried in a trench and/or a via-hole when a semiconductor device is fabricated.

In a semiconductor device of a damascene structure, an electro-plating process is usually used for gap-filling copper in the trench and the via-hole. Electrolyte used in the electro-plating process contains organic and inorganic components such as an accelerator and a suppressor as an additive for suppressing generation of the defects such as voids and/or seams. The organic additive contained in the electrolyte promotes a process of gap-filling copper in the trench. It is known that the density of the accelerator or the suppressor is a critical factor for determining whether or not defects such as voids and seams can be prevented in an initial stage of the gap-filling process. The accelerator raises a plating rate of a bottom-up super fill plating mode, in which the copper layer is grown from the bottom, rather than a conformal plating mode, in which the copper layer is grown in a direction perpendicular to the sidewall of the hole or trench. The suppressor prevents defects such as voids or seams as a result of an overhang generated by current flow concentrated on the neck of the hole or trench, while defects such as voids or seams can be generated in the hole or trench because an isogonal mode plating is promoted in an initial low current operation when density of the accelerator is too high. The additives used in the electro-plating process have a strong relationship with the defects such as voids or seams. Another factor related to defects, such as voids or seams, is an initial current condition. In other words, as an initial current in the plating is lower, the conformal plating mode becomes dominant rather than the bottom-up fill mode. Therefore, the initial current condition is critical and should be appropriately adjusted to an optimal value between the conformal plating mode and the bottom-up plating mode to prevent defects such as voids or seams. In addition, since the defects may be generated by bad electrical contact between a wafer surface and a copper seed layer, efforts have been made to upgrade structural components relating to the electrical contact. The present invention discusses a copper seed layer as another factor in addition to aforementioned ones. It was recognized that the possibility of generating voids or seams is very high when continuity of the copper seed layer is poor. Although the continuity can be improved and the defects such as voids or seams can be prevented by increasing the thickness of the copper seed layer, the increased thickness of the copper seed layer accordingly increases the number of the overhang portions, so that the possibility of generating voids in a subsequent copper plating process also increases. Therefore, the present invention addresses optimization of the thickness of the copper seed layer for preventing defects such as voids or seams.

In order to solve the aforementioned problems, the present invention provides a method of forming a metal wiring in a semiconductor device, the method comprising processes of: forming a first metal wiring on a semiconductor substrate; forming an etch stopping layer and an interlayer insulation film on the semiconductor substrate including the first metal wiring; selectively removing the interlayer insulation film to provide a trench; selectively removing the etch stopping layer exposed through the via-hole to expose a surface of the first metal wiring; forming an oxidation film on an entire surface of the semiconductor substrate including the trench and the via-hole; performing a de-gas process on the semiconductor substrate; removing the oxidation film; forming a metal diffusion barrier film on an entire surface of the semiconductor substrate including the trench and the via-hole; forming a metal seed layer having a thickness of 750 through 850 on the metal diffusion barrier film; and forming a second metal wiring on the metal seed layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a semiconductor device fabricated in accordance with a conventional metal wiring method;

FIGS. 2A, 2B, 2C, 2D, 2E, 2F, and 2G are cross-sectional views illustrating a semiconductor device fabricated by a metal wiring fabrication method according to the present invention;

FIG. 3 is a graph showing how many defects are generated in a semiconductor device depending on the thickness of the copper seed layer; and

FIG. 4 shows the semiconductor device after an electron-beam exposure.

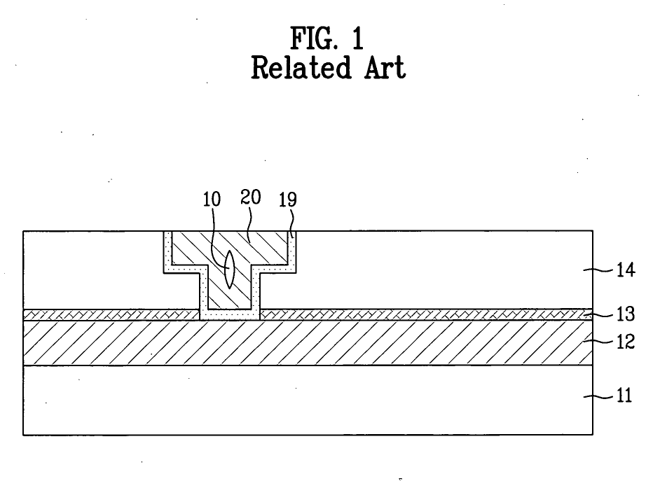

### DETAILED DESCRIPTION OF THE ILLUSTRATED EMBODIMENTS

Hereinafter, exemplary embodiments of a method of forming a metal wiring in a semiconductor device according to the present invention will be described in detail with reference to the accompanying drawings.

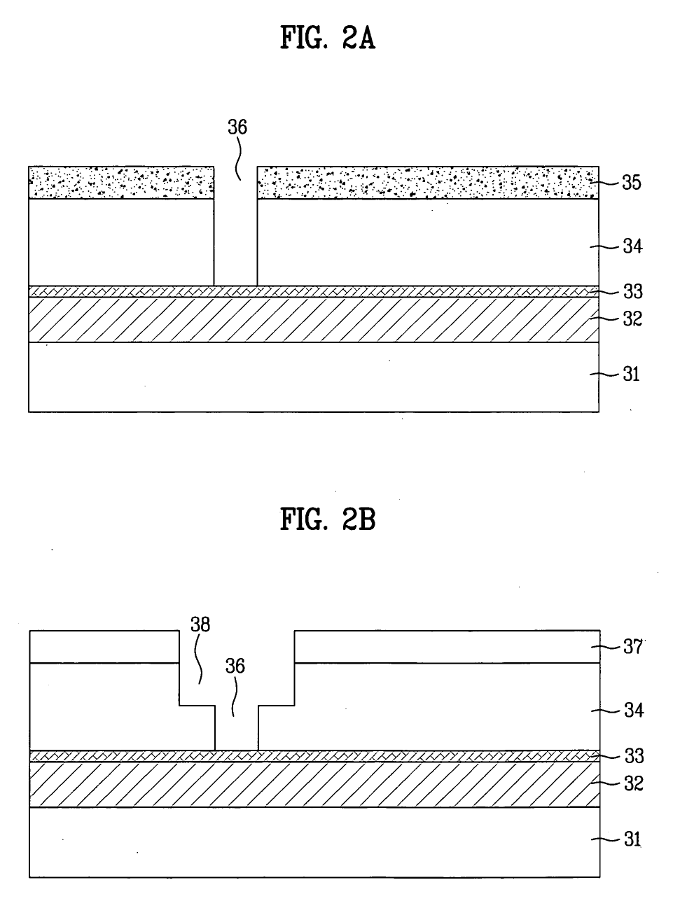

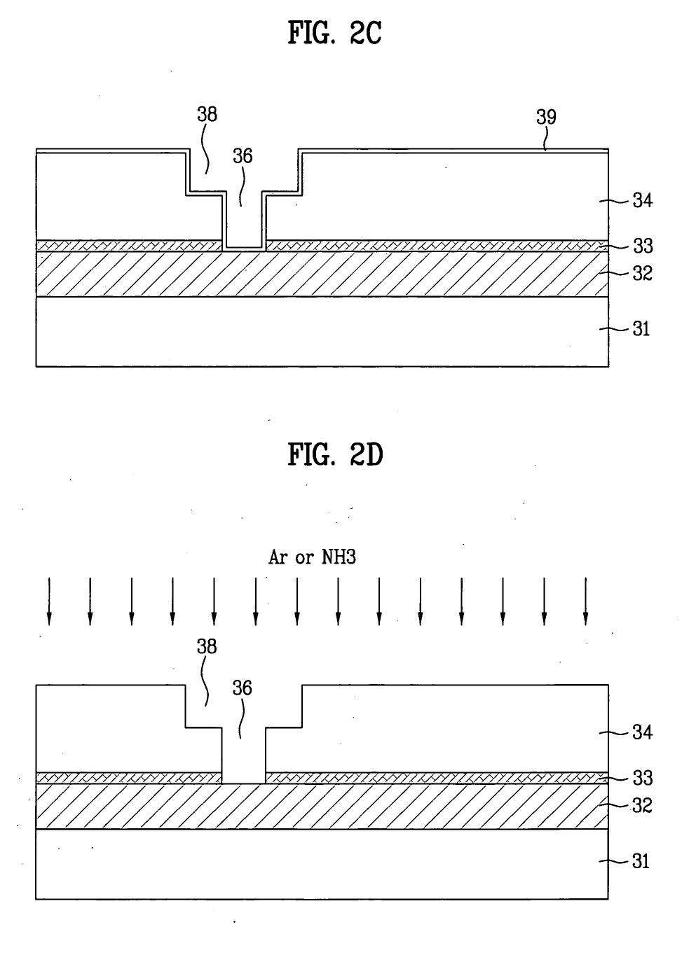

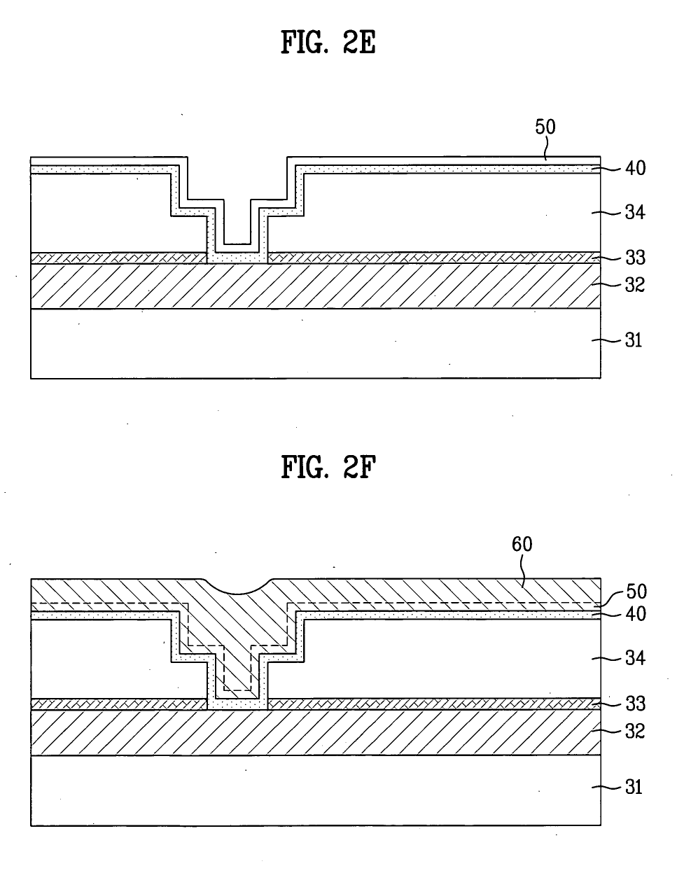

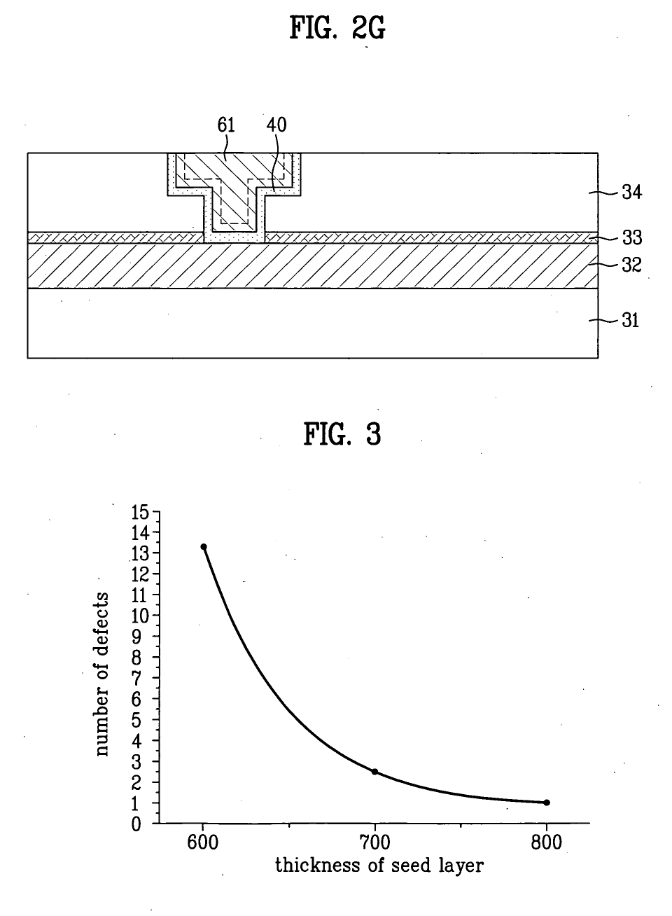

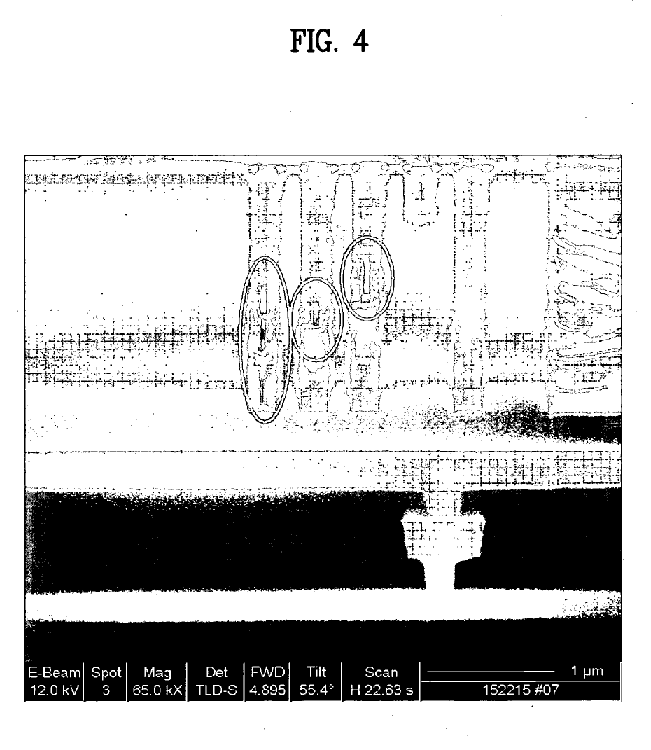

FIGS. 2A through 2G are cross-sectional views illustrating a method of forming a metal wiring in a semiconductor device according to an exemplary embodiment of the present invention.

Referring to FIG. 2A a first copper thin film is formed on a semiconductor substrate 31 (or a dielectric film), and then the first copper thin film is selectively removed through photolithography and etching processes to provide a first copper wiring 32. Subsequently, a nitride film 33 is formed on the entire surface of the semiconductor substrate 31, including the first copper wiring 32, and an interlayer insulation film 34 is formed on the nitride film 33. The nitride film 33 is configured to serve as an etch stopping film. Then, a first photo-resist 35 is formed on the interlayer insulation film 34, and the first photo-resist 35 is patterned through photolithography and development processes to define a contact area. In addition, the interlayer insulation film 34 is selectively removed by using the first photo-resist 35 having a pattern as a mask and using the nitride film 33 as an etching end point to form a via-hole 36.

Referring to FIG. 2B, after the first photo-resist 35 is removed, a second photo-resist 37 is formed on the entire surface of the semiconductor substrate 31, including the via-hole 36, and then, the second photo-resist 37 is patterned through the photolithography and development processes. Subsequently, a predetermined thickness of the interlayer insulation film 34 is selectively removed from the surface by using the second photo-resist 37 having a pattern as a mask to form a trench 38.

Referring to FIG. 2C, after the second photo-resist 37 is removed, the nitride film 33 remaining at the bottom of the via-hole 36 is etched off. When the nitride film 33 is etched off, the second photo-resist 37 or the interlayer insulation film 34 may be used as a mask. Subsequently, an oxidation film 39 having a thickness in a range of 10 to 30 Å is formed on the entire surface of the semiconductor substrate 31. In addition, a de-gas process is executed to remove impurities such as moisture from the semiconductor substrate 31 having an oxidation film 39. The de-gas process may be performed by applying a thermal treatment using a de-gas chamber in a film deposition machine at a temperature in a range of 350 to 500° C. for a time period in a range of 20 to 100 seconds.

Referring to FIG. 2D, after the de-gas process is performed with the oxidation film 39 being provided, the oxidation film 39 is removed through sputter etching in a high vacuum atmosphere. More specifically, the oxidation film 39 is removed by applying a DC bias voltage in a range of 40-600 V, an RF supply power in a range of 100-700 W, and inflowing Ar or NH3 into the sputter chamber at a gas pressure of 0.1˜3 mtorr. In other words, after the nitride film 33 remaining at the bottom of the via-hole 36 is etched off, an oxidation film 39 having a thickness in a range of 10 to 30 Å is formed on the semiconductor substrate 31 before the de-gas process. Then, the oxidation film 39 is removed through sputter etching, and subsequent processes are performed. When the oxidation film 39 is removed through sputter etching, fluoric or carbon components existing on the surface of the interlayer insulation film 34 are removed.

Referring to FIG. 2E, a metal diffusion barrier film 40 is formed by depositing a conductive material on the entire surface of the semiconductor substrate 31, including the trench 38 and via-hole 36. The metal diffusion barrier film 40 may be formed by depositing a material selected from a group consisting of TiN, Ta, TaN, WNX, and TiAl(N) comprising a thickness in a range of 10-1000 Å through a physical or chemical vapor deposition process. The metal diffusion barrier film 40 is configured to serve as a barrier for preventing copper atoms from being diffused from a copper thin film, which will be formed later, to the interlayer insulation film 34. Subsequently, a copper seed layer 50 is formed on the metal diffusion barrier film 40. The copper seed layer 50 may have a thickness in a range of 750-850 Å, preferably, about 800 Å.

Experiments have been made on how many defects such as voids or seams are generated depending on the thickness of the copper seed layer 50. Referring to FIG. 3, it is recognized that the number of the defects is minimized when the thickness of the copper seed layer 50 is about 800 Å.

Returning to FIG. 2F, a second copper thin film 60 is formed on the copper seed layer 50 through an electrochemical copper plating technique by using the copper seed layer 50 as a seed.

In the electro-plating process, deposition of a safe and clean copper seed layer is an indispensable process. Alternatively, the diffusion barrier film and the copper seed layer may be deposited in a deposition machine including a PVD chamber as well as a CVD chamber, and then, the electro-plating of copper may be performed in a copper electro-plating machine. The copper thin film is formed by depositing copper on the copper seed layer through a metal-organic chemical vapor deposition (MOCVD) process or an electro-plating process without a vacuum break after the copper seed layer is formed.

In this case, if the copper thin film is deposited through the MOCVD process, the deposition is performed at a temperature of 50 through 300° C., and a precursor is provided at a flow rate of 5 through 100 sccm (standard cubic centimeter per minute). The precursor may be a mixture of (hfac)CuTMVS and additives, a mixture of (hfac)CuVTMOS and additives, or a mixture of (hfac)CuPENTENE and additives.

In addition, when the copper thin film is formed through the electro-plating process, the copper is deposited at a low temperature in a range of −20 to 150° C. without a vacuum break after the copper seed layer is formed.

Referring to FIG. 2G, a chemical mechanical polishing (CMP) process is performed for the second copper thin film 60 by using a top surface of the interlayer insulation film 34 as a polishing stop level or indicator to selectively remove the second copper thin film 60, the copper seed layer 50, and the interlayer insulation barrier film 40. As a result, a second copper wiring 61 is provided inside the trench 38 and the via-hole 36.

Although the oxidation film 39 is removed through an RF plasma process in the present embodiment, the aforementioned processes from the etch-off of the nitride film 33 to the deposition of the second copper thin film 41 a may be performed without removing the oxidation film 39 and without delay time and vacuum break.

According to the present invention, defects such as voids, or seams in the metal layer, are prevented from being buried in the trench and/or the via-hole when a semiconductor device is fabricated. Therefore, the reliability of a device is improved.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in a descriptive sense only and not for purposes of limitation. Therefore, the scope of the invention is defined not by the detailed description of the invention but by the appended claims, and all differences within the scope will be construed as being included in the present invention.

What is claimed is:

1. A method of forming metal wiring in a semiconductor device, the method comprising:
forming a first metal wiring on a semiconductor substrate;
forming an etch stopping layer and an interlayer insulation film on the semiconductor substrate including the first metal wiring;
selectively removing a portion of the interlayer insulation film to provide a via-hole;
selectively removing a portion of the interlayer insulation film to provide a trench;
selectively removing the etch stopping layer exposed through the via-hole to expose a surface of the first metal wiring;
forming an oxidation film on an entire surface of the semiconductor substrate including the trench and the via-hole;
performing a de-gas process on the semiconductor substrate;
removing the oxidation film;
forming a metal diffusion barrier film on an entire surface of the semiconductor substrate including the trench and the via-hole;
forming a metal seed layer having a thickness in a range of 750 to 850 Å on the metal diffusion barrier film; and
forming a second metal wiring on the metal seed layer.

2. The method according to claim 1, wherein the metal seed layer has a uniform thickness of 800 Å.

3. The method according to claim 1, wherein the oxidation film has a thickness in a range of 10 to 30 Å.

4. The method according to claim 1, wherein the oxidation film is removed through sputter etching.

5. The method according to claim 1, further comprising:
removing the oxidation film by inflowing Ar or NH₃ into a sputter chamber at a gas pressure in a range of 0.1 to 3 mtorr; and
applying a DC bias voltage in a range of 40 to 600 V and a RF supply power in a range of 100 to 700 W.

6. The method according to claim 1, wherein processes from the etching of the etch stopping layer to the deposition of a metallic film for forming the second metal wiring are performed without a vacuum break.

7. A method of forming metal wiring in a semiconductor device, the method comprising:
preparing a semiconductor substrate;
forming a metal seed layer having uniform thickness in a range 750-850 Å on the semiconductor substrate; and
forming a metal layer on the metal seed layer.

8. The method according to claim 7, wherein the metal layer is formed through electroplating.

9. The method according to claim 7, wherein the semiconductor substrate includes a structure having a trench.

10. The method according to claim 9, wherein the metal seed layer and the metal layer are formed on the trench.

11. The method according to claim 7, wherein the metal seed layer is formed on a metal diffusion barrier film on the semiconductor substrate.

12. The method according to claim 11, wherein the metal diffusion barrier film includes a portion in contact with another metal layer on the semiconductor substrate.
